(19) United States
(12) Patent Application Publication
(10) Pub. No.: US 2025/0389764 A1
(43) Pub. Date: Dec. 25, 2025

(54) EVALUATING COPPER PLATING IN A PTH

(71) Applicant: International Business Machines Corporation, Armonk, NY (US)

(72) Inventors: Abdikarim Hussein, Rochester, MN (US); Asa Clifford Guest, Rochester, MN (US); Egduard Ramon Jauregui, Aurora, CO (US); Emma Quinn, Rochester, MN (US)

(21) Appl. No.: 18/747,826

(22) Filed: Jun. 19, 2024

(51) Int. Cl. G01R 31/28; G01R 1/067; H05K 1/11

(52) U.S. Cl. CPC G01R 31/2813; G01R 1/06705; H05K 1/115; H05K 2201/09545; H05K 2203/162

(57) ABSTRACT

A device comprising a connector configured to electrically connect a measurement device on an annular ring on a first side of a Plated Through Hole (PTH), a probe connected to the measurement device and configured to touch an interior wall of the PTH at a first location, a motor control and a motor to move the probe in the PTH, and a sensor, in the measurement device, to detect electrical measurements through the PTH from the connector to the probe.

Plated Through Hole (PTH) technology is a mainstay in Printed Circuit Board (PCB) technology. It supports robust electrical and mechanical connections, making it indispensable in industries like aerospace, automotive, and industrial equipment. While Surface Mount Technology (SMT) dominates due to its ability to support higher component densities and automated assembly, PTH is still essential for components that require secure mounting and for multi-layer interconnections. Current advancements in PTH technology focus on improving manufacturing precision and material quality to enhance performance and durability.

In the current generation of Printed Circuit Board (PCB) products, the aspect ratios continue to become larger, and the accuracy of backdrill depth becomes more vital.

Many main planar boards and IO cards had or were suspected of having thin or missing plating defects in backdrilled holes and were found to have longer back drill stubs. Current backdrill stub tolerance is 9±5 mils.

New quality assurance methods must be developed to decrease the probability of defective backdrilled PTHs escaping quality checks. Common PTH failure points include cracking due to thermal stress, opens developed during the manufacturing process, oxidation, and longer back drill stub detriments affecting signal integrity at higher speeds.

PCB suppliers continually have issues with thin plating in backdrilled plated through holes and out of spec backdrill stubs. Millions of dollars of product has been recalled and caused disruption to delivering systems to customers on time. The defects that made it into systems required additional internal resources to monitor system performance through its life.

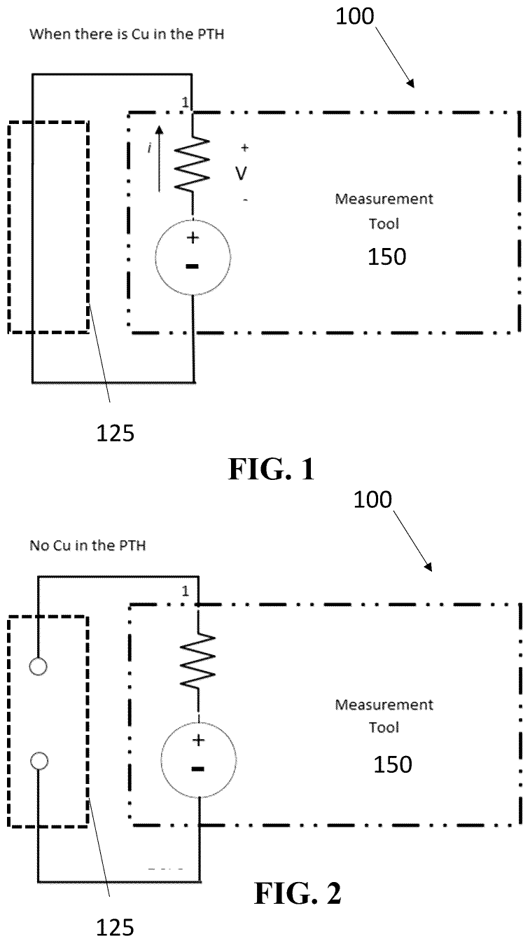

In some embodiments, a testing device that uses a probe to detect copper along the PTH wall to test for electrical continuity is proposed. In some embodiments, the proposed test differs from other electrical tests for testing backdrilled holes (4-wire testing) as it can detect missing plating in parts of the PTH by physically probing various locations. In some embodiments, as the proposed method is an electrical test, there is less propensity to miss defects of lesser severity. FIGS. 1 and 2 show examples of circuit 100 when copper is/is not present with the proposed test. In some embodiments, the example circuit 100 may include a measurement tool 150 and a region 125 representing the PTH. FIG. 1. depicts a schematic of closed loop when copper is present in the PTH. FIG. 2 depicts a schematic of an open loop when copper is absent in the PTH. In some embodiments, the measuring device can be an Analog or a Digital Multimeter (AMM/DMM) capable of measuring resistance.

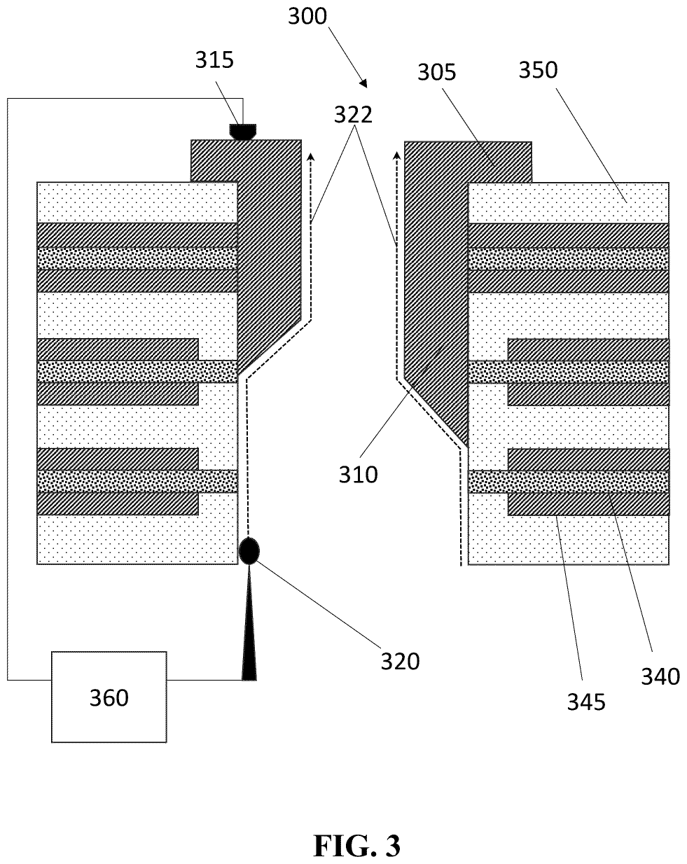

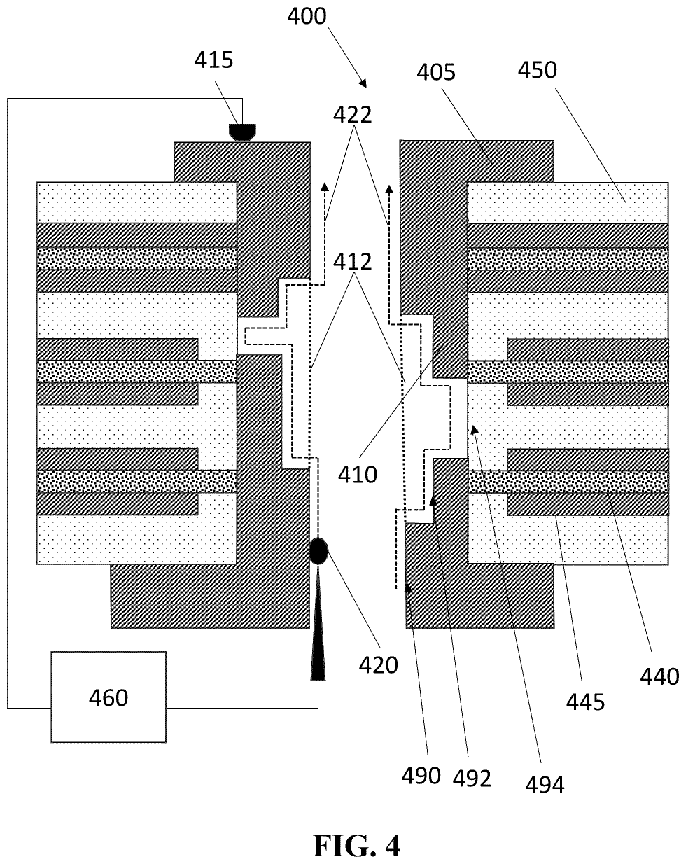

FIG. 3 depicts a cross sectional slice view of exemplary PTH 300 in PCB 350 with example testing components. In some embodiments, only the section of PCB 350 with PTH 300 is depicted. PCB 350 may have many PTHs and other components (not depicted) outside of the small section depicted in FIG. 3. In some embodiments, copper has been plated on PTH 300 forming annular ring 305 on a first side of the PCB/PTH and copper plating 310 on the walls of the PTH. In FIG. 3, the copper has not been deposited uniformly, depicted by the left side of plating 310 not extending as far as the right side of plating 310 where copper plating was intended to be deposited uniformly through the PTH 300. In some embodiments, a connector 315 may be placed on annular ring 305. In some embodiments, connector 315 is a conductive material made to interface with a metal contact such as annular ring 305. In some embodiments, connector 315 may be connected to measurement tool 360. In some embodiments, PCB 350 may include one or more layers of conductive material 340 and dielectric 345 or other materials (not depicted) used in multilayer PCBs. In some embodiments, a probe 320, connected to measurement tool 360, may be inserted into the PTH 300 and placed against the surface of the PTH 300 making contact with the PTH 300. In some embodiments, the probe may be directed along a path such as path 322. In some embodiments, the probe may be used by measurement tool 360 to take and record several measurements along the interior surface of PTH as the probe travels along the path 322 to one or more locations. In some embodiments, the measurements may be from electrical currents and/or voltage, applied by measurement tool 360, running from the annular ring to the copper plating 310. Possible paths will be discussed further below. In some embodiments, the device includes connector 315, measurement tool 360, probe 320, a motor (not depicted), and a motor controller (not depicted). One skilled in the art will understand that the device may take on multiple configurations and need other components to implement the device. In some embodiments, measurement tool 360 may have one or more sensors configured to detect electrical measurements such as a current, voltage, voltage drop, or resistance from connector 315 to probe 320.

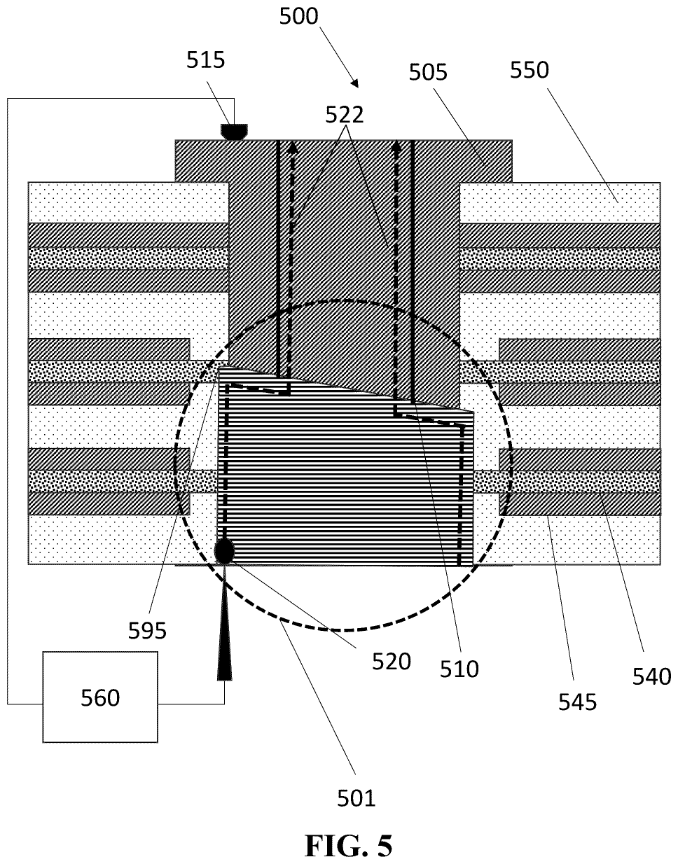

FIG. 5 depicts a cross sectional view of an exemplary PTH 500 in PCB 550. In the previous views, only thin slice of a PCB was shown, in FIG. 5 the cross sectional view also depicts the section of PCB 550 behind the cross sectional plane (e.g., the visible back wall of PTH 500). In some embodiments, only the section of PCB 550 with the PTH 500 is depicted. PCB 550 may have many PTH and other components (not depicted) outside of the small section depicted in FIG. 5. In some embodiments, copper has been plated on the PTH 500 forming annular ring 505 and copper plating 510 on the walls of the PTH 500. In FIG. 5, the copper has not been deposited uniformly, depicted by the steps in plating 510 where copper plating was intended to be deposited uniformly through the PTH 500. For example, In FIG. 5, the PTH 500 was intended to have a uniform coating completely covering the conductive material at point 595. In some embodiments, a connection point 515 may be placed on annular ring 505. In some embodiments, connection point 515 may be connected to measurement tool 560. In some embodiments, PCB 550 may include one or more layers of conductive material 540 and dielectric 545 or other materials (not depicted) used in multilayer PCBs. In some embodiments, a probe 520, connected to measurement tool 560, may be inserted into the PTH 500 and placed against the surface of the PTH 500. In some embodiments, the probe may be directed along a path such as path 522. In some embodiments, the probe may take several measurements along the interior surface of the PTH 500 as it travels along the path 522. In some embodiments, the PTH 500 has been backdrilled, see area 501. In some embodiments, probe 520 may detect the depth of the backdrilling. For example, in FIG. 5 if backdrilling was intended to leave a complete connection between conductive material 541 and copper plating 510, however as depicted the backdrilling removed material from the interface at point 595. In some embodiments, the probe may detect that no copper is present bellow point 595 and thus the backdrilling may have removed more material than intended. For example, since more material was removed than was intended the interface between copper plating and the conductive material 541 may be compromised.

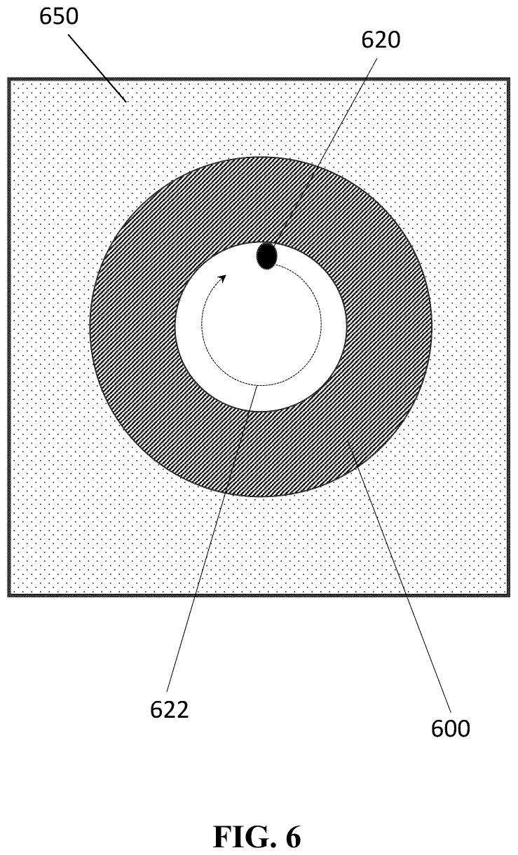

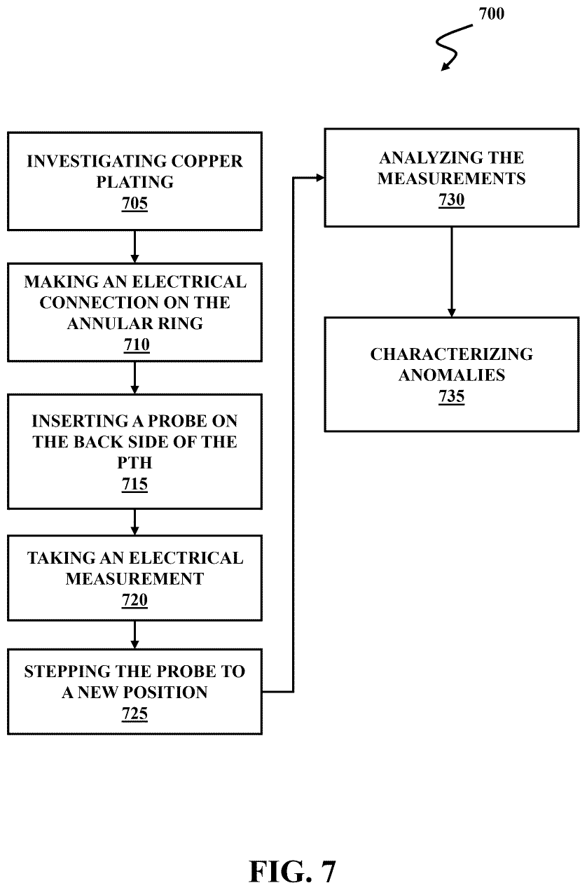

FIG. 6 depicts a top down view of PCB 650 with a PTH 600. In some embodiments, path 622 depicts a path that a probe 620 may follow. In some embodiments, path 622 may be used in combination with paths (e.g., path 322, 422, and 522) going into and out of the PTH 600. For example, probe 620 may corkscrew around the walls of PTH 600 going deeper with each revolution. For example, the probe may complete a complete a first circle around the wall of the PTH 600 at a first dept and then move deeper incrementally completing subsequent circles around the walls of the PTH 600. For example, the probe 620 may move deeper into the PTH 600 and then withdraw to the edge of the PTH 600 before rotating incrementally around the wall of the PTH 600 and repeating the process. In some embodiments, as the advances along the path it may stop incrementally to take measurements, or the system may take measurements as the probe 620 is moving. As will be understood by one skilled in the art, the path that the probe 620 follows may be designed to investigate a particular failure point or feature consideration. In some embodiments, a location of the probe 620 is based on velocity and time measurements recorded during movement of the probe 620.

Method 700 begins with operation 705 of forming a PTH in a PCB. In some embodiments, the PTH may be formed in a hole in the multilayer PCB. In some embodiments, copper plating is intended to be uniformly deposited in the hole. In some instances, a PTH may be created by drilling and plating a hole through the PCB to create connections between layers. The PTH may have an annular ring (e.g., a capture pad) at one end or both ends). In some embodiments, after the necessary connections are established, a secondary drilling process, known as backdrilling may be performed. In some instances, backdrilling removes the unused portion of the hole, called the stub, which extends beyond the last connected layer. This removal reduces signal reflections and interference caused by the stub, resulting in cleaner signal transmission and improved performance of high-speed circuits.

What is claimed is:

1. A device comprising:
a connector configured to electrically connect a measurement device on an annular ring on a first side of a Plated Through Hole (PTH);
a probe connected to the measurement device and configured to touch an interior wall of the PTH at a first location;
a motor control and a motor to move the probe in the PTH; and
a sensor, in the measurement device, to detect electrical measurements through the PTH from the connector to the probe.

2. The device of claim 1, wherein the measurement device is configured to detect a voltage drop through the PTH from the annular ring to the probe.

3. The device of claim 1, wherein the measurement device is configured to detect a current running from the annular ring to the probe given an applied voltage.

4. The device of claim 1, wherein the motor is configured to incrementally step the probe along an interior surface of the PTH.

5. The device of claim 1, wherein the first location of the probe is based on velocity and time measurements recorded during movement of the probe.

6. The device of claim 1, wherein an anomalous reading at a position indicates an absence of a coating at the position.

7. A method comprising:
forming a connection with a connector with an annular ring on a first side of a Plated Through Hole (PTH);
inserting a probe into the PTH from a second end of the PTH;
making contact between the probe an interior wall of the PTH; and
taking a measurement of electrical properties of the PTH between the connector and the probe.

8. The method of claim 7, further comprising:
recording a position of the measurement based on the velocity, direction, and travel time of the probe.

9. The method of claim 8 further comprising:
determining if the measurement is outside of an acceptable measurement parameter; and
recording the position as an anomalous reading.

10. The method of claim 9,
calculating, based on a determination that the measurement is outside of the acceptable measurement parameter, a resistive value, wherein the calculating is based on a current reading at the probe with a known voltage being applied at the annular ring.

11. The method of claim 9 further comprising:
determining, based on a resistance measurement above a threshold, that there is an absence of a coating at a position of the anomalous reading.

12. The method of claim 7 further comprising:
moving the probe to a new position along the interior wall of the PTH; and
measuring the electrical properties of the PTH between the connector and the probe at the new position.

13. The method of claim 7 further comprising:
repeating the moving and measuring at to record measurements at set points along the PTH.

14. The method of claim 7 further comprising:
applying a voltage to the annular ring through the connector.

15. A method comprising:
drilling a hole in a PCB;
depositing copper in the hole to form a Plated Through Hole (PTH) with an annular ring on a first side of the PTH;
forming a connection between a measurement device and the annular ring;
inserting a probe, connected to the measurement device, into a second side of the PTH;
touching the probe to a point on an interior surface of the PTH; and
taking a reading of electrical properties of the PTH between the probe and the annular ring.

16. The method of claim 15, further comprising:
recording a position of the measurement based on the velocity, direction, and travel time of the probe.

17. The method of claim 16 further comprising:
determining if the measurement is outside of an acceptable reading; and
recording the position as an anomalous reading.

18. The method of claim 17,
calculating, based on a determination that the measurement is outside of an acceptable reading, a resistive value, wherein the calculating is based on a current reading at the probe with a known voltage being applied at the annular ring.

19. The method of claim 17 further comprising:
determining, based on a resistance measurement above a threshold, that there is an absence of the coating at the position of the anomalous reading.

20. The method of claim 15 further comprising:
moving the probe to a new position along the interior wall of the PTH; and
measuring the electrical properties of the PTH between the connector and the probe at the new position.
